(19) United States
(12) Patent Application Publication
(10) Pub. No.: US 2025/0068078 A1
(43) Pub. Date: Feb. 27, 2025

(54) OPTICAL SYSTEM, LITHOGRAPHY APPARATUS HAVING AN OPTICAL SYSTEM, AND METHOD FOR PRODUCING AN OPTICAL SYSTEM

(71) Applicant: Carl Zeiss SMT GmbH, Oberkochen (DE)

(72) Inventor: Mohammad Awad, Heidenheim (DE)

(21) Appl. No.: 18/940,290

(22) Filed: Nov. 7, 2024

Related U.S. Application Data
(63) Continuation of application No. PCT/EP2023/062198, filed on May 9, 2023.

(30) Foreign Application Priority Data
May 12, 2022 (DE) 10 2022 204 643.9

(51) Int. Cl. G03F 7/20; H05K 1/02; H05K 1/18

(52) U.S. Cl. CPC G03F 7/2004; H05K 1/028; H05K 1/189

(57) ABSTRACT

An optical system for a lithography apparatus has an arrangement comprising a printed circuit board having at least one flexible region in which a flexible component comprising an integrated circuit is arranged.

### CROSS-REFERENCE TO RELATED APPLICATIONS

The present application is a continuation of, and claims benefit under 35 USC 120 to, international application No. PCT/EP2023/062198, filed May 9, 2023, which claims benefit under 35 USC 119 of German Application No. 10 2022 204 643.9, filed May 12, 2022. The entire disclosure of each of these applications is incorporated by reference herein.

### FIELD

The present disclosure relates to an optical system, to a lithography apparatus having such an optical system, and to a method for producing such an optical system.

### BACKGROUND

Microlithography is used for producing microstructured component parts, such as for example integrated circuits. The microlithography process is performed using a lithography apparatus, which has an illumination system and a projection system. The image of a mask (reticle) illuminated via the illumination system is in this case projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range from 0.1 nm to 30 nm, for example 13.5 nm, are currently under development. Since most materials absorb light of this wavelength, such EUV lithography apparatuses typically use reflective optics, which is to say mirrors, instead of—as previously—refractive optics, which is to say lenses.

A large number of actuator/sensor devices, such as sensors and actuators, are often installed in lithography apparatuses. In general, an actuator/sensor device is suitable for displacing an optical element, for example a mirror, assigned to the actuator/sensor device and/or for detecting a parameter of the assigned optical element, for instance a position of the assigned optical element or a temperature of the assigned optical element. For control and evaluation purposes, such an actuator/sensor device is usually electrically connected to an integrated circuit (IC). Integrated circuits are placed on printed circuit boards (also referred to as circuit boards), and the printed circuit boards with components fitted are usually installed in the lithography apparatus. However, the installation space in a lithography apparatus is typically very restricted, and hence the installation space for the printed circuit board with the placed ICs to be installed is also typically restricted. By way of example, should a position outside of the lithography apparatus, for example outside of the vacuum housing of the lithography apparatus, be chosen as the position for an integrated circuit electrically connected to such an actuator/sensor device, then this usually results in long transmission paths and can cause a poor signal integrity of the signals interchanged between the integrated circuit and the actuator/sensor device.

### SUMMARY

The present disclosure seeks to provide an improved optical system.

According to a first aspect, an optical system for a lithography apparatus is proposed, the optical system having an arrangement comprising a printed circuit board having at least one flexible region in which a flexible component comprising an integrated circuit is arranged.

Arranging the flexible component, and hence integrated circuit (IC), in the flexible region of the printed circuit board can result in significantly increased flexibility when installing the integrated circuit in the lithography apparatus. This can be desirable in light of the prevalent installation space restrictions within lithography apparatuses.

Additionally, it can be consequently possible to install in the lithography apparatus integrated circuits even in the bent state. This can reduce or prevent possible disturbances of an actuator/sensor device connected to the integrated circuit.

Such possible disturbances comprise, for example, disturbances as a result of heat and electromagnetic interference generated by the integrated circuit. On account of the flexibility of the flexible printed circuit board and the flexible IC, it is possible within applications to minimize the length of electrical lines used to connect the IC and actuator/sensor device to one another. Such minimization of the length of the electrical lines also can reduce signal path lengths and hence reduces the influence of possible disturbances within the scope of data transfer and control. Reducing the heat input at the assigned actuator/sensor device from the IC also can bring about a reduced thermal load on the optics.

The flexible region of the printed circuit board may also be referred to as a bendable region. The flexible component may also be referred to as a bendable component. Accordingly, the flexible integrated circuit may also be referred to as a bendable integrated circuit, or else as a flexible IC or flex IC.

The optical system can be a projection optical unit of the lithography apparatus or projection exposure apparatus. However, the optical system may also be an illumination system. The projection exposure apparatus may be an EUV lithography apparatus. EUV stands for “extreme ultraviolet” and denotes a wavelength of the working light of between 0.1 nm and 30 nm. The projection exposure apparatus may also be a DUV lithography apparatus. DUV stands for “deep ultraviolet” and denotes a wavelength of the working light of between 30 nm and 465 nm.

According to an embodiment, the flexible component comprises a logic module, a processor, an analogue-digital converter and/or a digital-analogue converter.

According to an embodiment, the flexible component comprises a flexible substrate, on which the integrated circuit is arranged.

According to an embodiment, the flexible component comprises a flexible substrate, on which the integrated circuit is manufactured.

According to an embodiment, the flexible region of the printed circuit board and the component arranged on the flexible region are in a bent state when arranged, such as when installed in the optical system. In applications, such a bent state can provide installation space-specific features. Further, possible disturbances of an actuator/sensor device connected to the integrated circuit can be reduced or prevented as a result of the one bent state.

According to an embodiment, the flexible region of the printed circuit board has a specific curvature and is in a bent state when arranged, such as when installed, in the optical system, with the component arranged on the flexible region being arranged away from the specified curvature.

According to an embodiment, the printed circuit board integrates the at least one flexible region and the flexible component comprising the integrated circuit.

According to an embodiment, the printed circuit board comprises the at least one flexible region and at least one rigid region connected to the flexible region.

According to an embodiment, the printed circuit board comprises two rigid regions, between which the flexible region is arranged.

According to an embodiment, the optical system further comprises a number of actuator/sensor devices, with the flexible component being connected to the number of actuator/sensor devices using at least one conductor track of the printed circuit board. For example, the respective actuator/sensor device is an actuator (or actuating element) for actuating an optical element, a sensor for sensing an optical element or surroundings within the optical system, or an actuator and sensor device for actuating and sensing within the optical system. By way of example, the sensor is a temperature sensor. The actuator can be an actuator using the electrostrictive effect or an actuator using the piezoelectric effect, for example a PMN actuator (PMN; lead magnesium niobate) or a PZT actuator (PZT; lead zirconate titanate). The actuator is configured, for example, to actuate an optical element of the optical system. Examples of such an optical element include lens elements, mirrors and adaptive mirrors.

According to an embodiment, the optical system comprises a number of displaceable optical elements for guiding radiation in the optical system, with at least one of the actuator/sensor devices being assigned to the respective optical element and with the respective actuator/sensor device being configured to displace the assigned optical element and/or to detect a parameter of the assigned optical element, for example a position of the assigned optical element or a temperature in the region of the assigned optical element.

According to an embodiment, the optical system comprises a vacuum housing in which the arrangement is arranged.

According to an embodiment, the optical system comprises a vacuum housing in which the arrangement, the number of actuator/sensor devices and the optical elements are arranged.

According to an embodiment, the optical system is in the form of an illumination optical unit or in the form of a projection optical unit of a lithography apparatus.

According to a second aspect, a lithography apparatus is proposed, which comprises an optical system according to the first aspect or according to one of the embodiments of the first aspect.

According to a third aspect, a method is proposed for producing an optical system for a lithography apparatus. The method comprises the steps of:
arranging in the optical system a printed circuit board having at least one flexible region, and
arranging on the flexible region of the printed circuit board a flexible component comprising an integrated circuit.

According to an embodiment, the flexible component is connected to an actuator/sensor device using at least two conductor tracks of the printed circuit board.

According to an embodiment, the position of the flexible component in the flexible region of the printed circuit board is chosen taking into account a predetermined, maximally allowable disturbance of the actuator/sensor device by the flexible component, for example with respect to a heat input and/or electromagnetic interference, in such a way that a length of an electrical connection between the flexible component and the actuator/sensor device is minimal.

A minimal length of the electrical connection between the flexible component and the actuator/sensor device can cause a maximally good signal integrity taking account of possible negative influences of the flexible component, for example with respect to waste heat and potential electromagnetic interference, on the actuator/sensor device.

The embodiments described for the proposed optical system apply correspondingly to the proposed method, and vice versa. Furthermore, the definitions and explanations in relation to the optical system also apply correspondingly to the proposed method.

“A” or “an” in the present case should not necessarily be understood to be restrictive to exactly one element. Rather, a plurality of elements, such as for example two, three or more, may also be provided. Any other numeral used here should also not be understood to the effect that there is a restriction to exactly the stated number of elements. Rather, unless indicated otherwise, numerical deviations upwards and downwards are possible.

Further possible implementations of the disclosure also comprise not explicitly mentioned combinations of features or embodiments that are described above or hereinafter with respect to the exemplary embodiments. In this case, a person skilled in the art will also add individual aspects as improvements or supplementations to the respective basic form of the disclosure.

Further features, configurations and aspects of the disclosure are the subject matter of the dependent claims and also of the exemplary embodiments of the disclosure described hereinafter. The disclosure is explained in greater detail hereinafter on the basis of embodiments with reference to the appended figures.

### BRIEF DESCRIPTION OF THE DRAWINGS

FIG. 1 shows a schematic meridional section of a projection exposure apparatus for an EUV projection lithography;

FIG. 2 shows a schematic illustration of an embodiment of an optical system;

FIG. 3 shows the embodiment of the optical system according to FIG. 1 with the arrangement in a bent state;

FIG. 4 shows a schematic illustration of an embodiment of an optical system;

FIG. 5 shows a schematic illustration of an embodiment of the flexible component of the optical system according to FIGS. 1 to 3;

FIG. 6 shows a schematic illustration of an embodiment of an optical system; and

FIG. 7 shows a schematic view of an embodiment of a method for producing an optical system for a lithography apparatus.

### DETAILED DESCRIPTION

Unless indicated otherwise, elements that are identical or functionally identical have been provided with the same reference signs in the figures. It should also be noted that the illustrations in the figures are not necessarily true to scale.

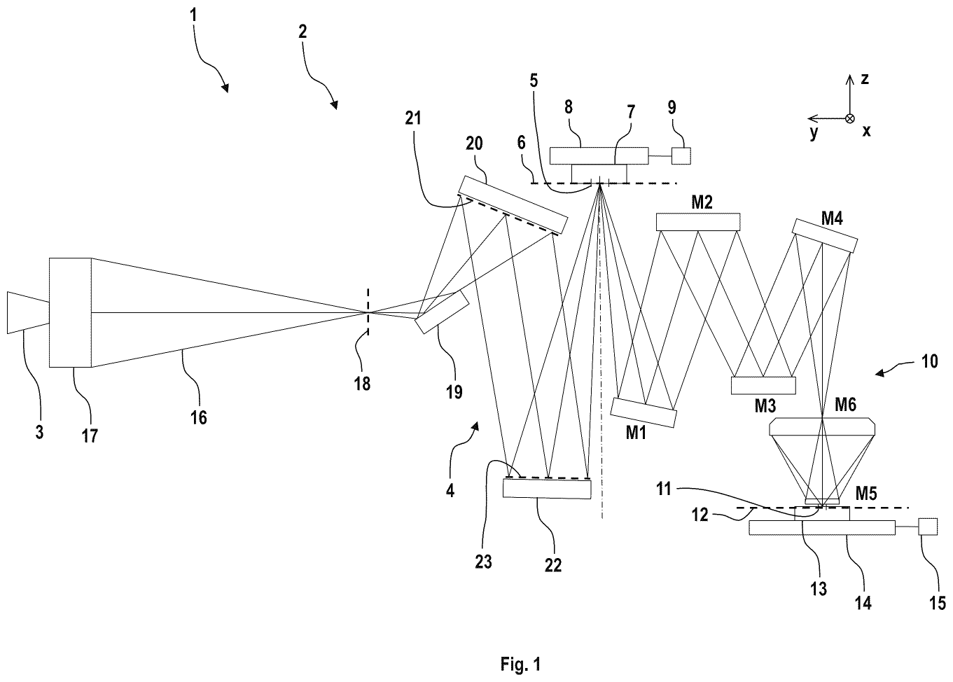

FIG. 1 shows an embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement, firstly, of the reticle 7 by way of the reticle displacement drive 9 and, secondly, of the wafer 13 by way of the wafer displacement drive 15 may be implemented so as to be mutually synchronized.

The light source 3 is an EUV radiation source. The light source 3 emits EUV radiation 16, which is also referred to below as used radiation, illumination radiation or illumination light. For example, the used radiation 16 has a wavelength in the range between 5 nm and 30 nm. The light source 3 may be a plasma source, for example an

LPP (short for: laser produced plasma) source or a DPP (short for: gas-discharge produced plasma) source. It may also be a synchrotron-based radiation source. The light source 3 may be an FEL (short for: free-electron laser).

The illumination radiation 16 emerging from the light source 3 is focused by a collector 17. The collector 17 can be a collector with one or more ellipsoidal and/or hyperboloidal reflection surfaces. The at least one reflection surface of the collector 17 may be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 can be structured and/or coated firstly for optimizing its reflectivity for the used radiation and secondly for suppressing extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. Alternatively or in addition, the deflection mirror 19 may be embodied in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, for example as rectangular facets or as facets with an arcuate edge contour or an edge contour of part of a circle. The first facets 21 may be embodied as plane facets or alternatively as facets with convex or concave curvature.

As known for example from DE 10 2008 009 600 A1, the first facets 21 themselves can also be composed in each case of a multiplicity of individual mirrors, for example a multiplicity of micromirrors. For example, the first facet mirror 20 can be embodied as a microelectromechanical system (MEMS system). For details, reference is made to DE 10 2008 009 600 A1.

Between the collector 17 and the deflection mirror 19, the illumination radiation 16 travels horizontally, which is to say in the y-direction y.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or hexagonal boundary, or may alternatively be facets composed of micromirrors. In this regard, reference is likewise made to DE 10 2008 009 600 A1.

The second facets 23 may have plane reflection surfaces or alternatively convexly or concavely curved reflection surfaces.

The illumination optical unit 4 consequently forms a doubly faceted system. This fundamental principle is also referred to as a fly's eye condenser (or integrator).

It can be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or indeed the last mirror for the illumination radiation 16 in the beam path upstream of the object field 5.

In a further embodiment (not shown) of the illumination optical unit 4, a transfer optical unit contributing for example to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit can comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are similarly possible. The projection optical unit 10 is a twice-obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings can be designed as multilayer coatings, for example with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may have an anamorphic form. It has for example different imaging scales βx, βy in the x-and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, which is to say in a direction perpendicular to the scanning direction.

The projection optical unit 10 leads to a reduction in size of 8:1 in the y-direction y, which is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x-and y-directions x, y are known from US 2018/0074303 A1.

In each case one of the second facets 23 is assigned to exactly one of the first facets 21 for respectively forming an illumination channel for illuminating the object field 5. This may produce illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 is for example as homogeneous as possible. It can have a uniformity error of less than 2%. The field uniformity can be achieved by overlaying different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, for example the subset of the second facets 23, which guide light. This intensity distribution is also referred to as illumination setting or illumination pupil filling.

A likewise preferred pupil uniformity in the region of sections of an illumination pupil of the illumination optical unit 4 which are illuminated in a defined manner may be achieved by a redistribution of the illumination channels.

Further aspects and details of the illumination of the object field 5 and for example of the entrance pupil of the projection optical unit 10 are described below.

The projection optical unit 10 may have for example a homocentric entrance pupil. The latter can be accessible. It can also be inaccessible.

The entrance pupil of the projection optical unit 10 frequently cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component part of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted in relation to an arrangement plane defined by the deflection mirror 19. The first facet mirror 20 is arranged so as to be tilted with respect to an arrangement plane defined by the second facet mirror 22.

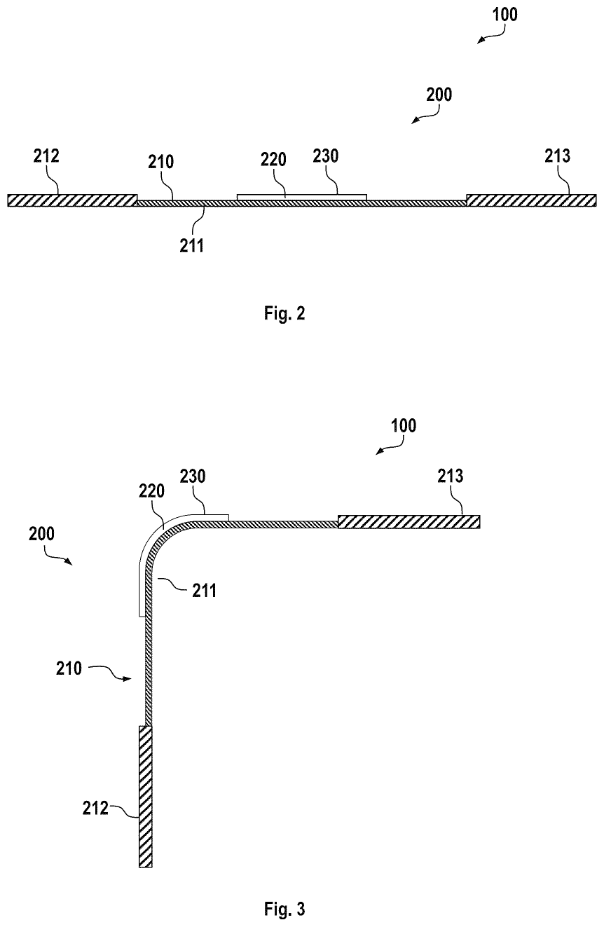

FIG. 2 shows a schematic illustration of an embodiment of an optical system 100 for a lithography apparatus or projection exposure apparatus 1, as shown in FIG. 1 for example. Additionally, the optical system 100 of FIG. 2 may also be used in a DUV lithography apparatus for example.

The optical system 100 has an arrangement 200 comprising a printed circuit board 210. The printed circuit board 210 has at least one flexible region 211. The exemplary embodiment of the printed circuit board 210 according to FIG. 2 comprises two rigid regions 212 and 213 in addition to the flexible region 211. By way of example, the flexible region 211 is arranged between the two rigid regions 212 and 213 in this case. For example, the rigid regions 212 and 213 are suitable for fastening purposes and for electronic contacting with a part of the optical system 100.

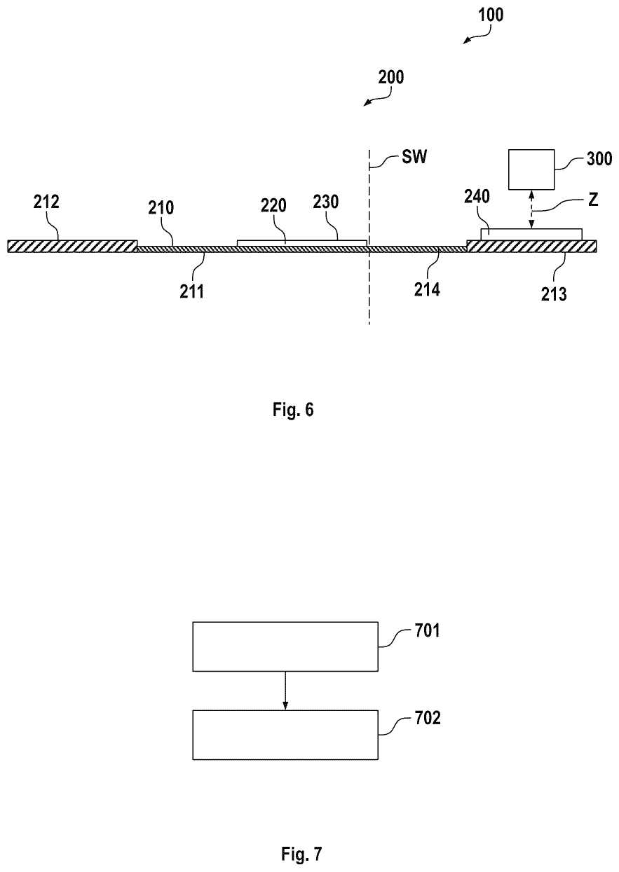

A flexible component 230 is arranged on the flexible region 211 of the printed circuit board 210. The flexible component 230 comprises at least one integrated circuit 220. The electrical connections between the flexible component 230 and the printed circuit board 210 or its conductor tracks 214 (see FIG. 6) have not been shown in FIG. 2 for reasons of clarity.

In this respect, FIG. 3 shows the optical system 100 according to FIG. 2, with the arrangement 200 having a bent state. In this case, the flexible region 211 of the printed circuit board 210 and the component 230 having the integrated circuit 220 arranged on the flexible region 211 are in a bent state when installed in the optical system 100. In applications, this bent state of the arrangement 200 provides installation space-specific features.

For example, the flexible component 230 comprises a logic module, a processor, an analogue-digital converter (ADC) and/or a digital-analogue converter (DAC). In other words, the integrated circuit 220 is hence designed so that it forms a logic module, a processor, an analogue-digital converter and/or a digital-analogue converter.

In this case, the flexible component 230 can comprise a flexible substrate. In this respect, FIG. 5 shows a schematic illustration of an embodiment of the flexible component 230. The flexible component 230 comprises a flexible substrate 231, on which the integrated circuit 220 is arranged. For example, the integrated circuit 220 is manufactured onto the flexible substrate 231, and the flexible component 230 is subsequently arranged on the flexible region 211 of the printed circuit board 210. Hence, the printed circuit board 210 can integrate the at least one flexible region 211 and the flexible component 230 comprising the integrated circuit 220. Further, the printed circuit board 210—as shown in FIGS. 2 to 4—can integrate the flexible region 211 with the flexible component 230 arranged thereon, and the rigid regions 212 and 213.

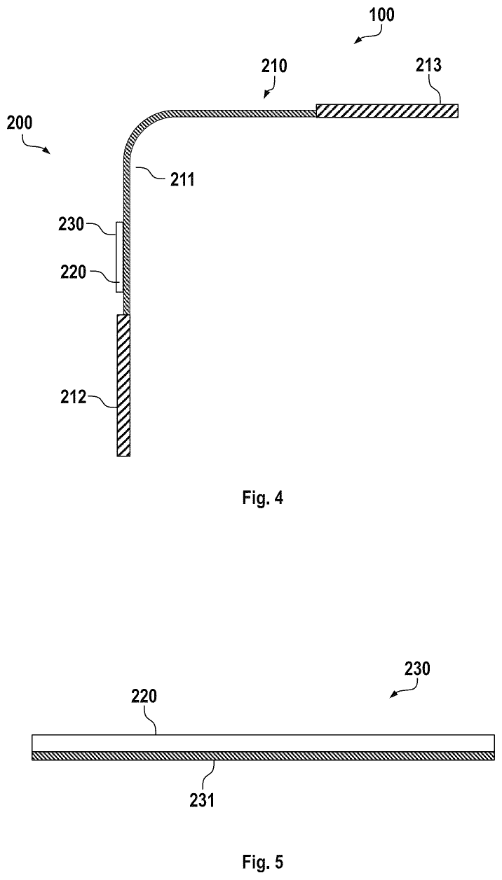

FIG. 4 shows a schematic illustration of a further embodiment of an optical system 100. Like in FIG. 3, the flexible region 211 of the printed circuit board 210 from FIG. 4 has a specific curvature and is in a bent state when arranged, such as when installed, in the optical system 100. In contrast to FIG. 3, the component 230 arranged on the flexible region 211 is arranged away from the specific curvature. In other words, the component 230 in FIG. 4 is arranged in a straight portion of the flexible region 211 of the printed circuit board 210.

FIG. 6 illustrates a schematic illustration of a further embodiment of an optical system 100. The further embodiment according to FIG. 6 is based on the embodiment of the optical system 100 according to FIGS. 2 to 5 and has all of the features described there. Moreover, the optical system 100 according to FIG. 6 comprises an actuator/sensor device 240 for an optical element. The actuator/sensor device 240 according to FIG. 6 is electrically connected to the rigid region 213 of the printed circuit board 210 and can be arranged on this rigid region 213. For example, the actuator/sensor device 240 is a temperature sensor or an actuator. In general, the actuator/sensor device 240 is configured to detect a parameter of the assigned optical element 300, for example a temperature in the region of the assigned optical element 300 or a position of the assigned optical element 300, and/or to displace the assigned optical element 300. By way of example, the optical element 300 is one of the mirrors M1 to M6 or one of the facet mirrors 20 to 23.

In FIG. 6, the assignment between the actuator/sensor device 240 and the optical element 300 is labelled by the dashed arrow provided with the reference sign Z.

Moreover, the reference sign SW in FIG. 6 denotes a threshold or a threshold value, up to which the flexible component 230 with the integrated circuit 220 can be arranged in relation to the actuator/sensor device 240. The threshold value SW is determined on the basis of a predetermined, maximally allowable disturbance of the actuator/sensor device 240 by the flexible component 230, for example with respect to a heat input and/or electromagnetic interference by the flexible component 230. Hence, the threshold value SW is calculated on the basis of the predetermined, maximally allowable disturbance by the flexible component 230, and the flexible component 230 is then arranged on the flexible region 211 of the printed circuit board 210 in such a way that a length of an electrical connection between the flexible component 230 and the actuator/sensor device 240 is minimal. What this achieves is that the flexible component 230 is brought as close as possible to the calculated threshold value SW. The minimal length of the electrical connection between the flexible component 230 and the actuator/sensor device 240 causes a maximally good signal integrity taking account of the influences of the flexible component 230, for example with respect to waste heat and electromagnetic compatibility, on the actuator/sensor device 240. In this way, the parameters of good signal integrity and minimization of negative influences of the flexible component 230 on the actuator/sensor device 240 are optimized.

FIG. 7 shows a schematic view of an embodiment of a method for producing an optical system 100 for a lithography apparatus 1. Examples of the optical system 100 are illustrated in FIGS. 2 to 6. An example of a lithography apparatus 1 having an optical system 4, 10 is illustrated in FIG. 1. The embodiment of the method according to FIG. 7 comprises steps 701 and 702.

In step 701, a printed circuit board 210 having at least one flexible region 211 is arranged, for example assembled, in the optical system 100.

In step 702, a flexible component 230 comprising an integrated circuit 220 is arranged on the flexible region 211 of the printed circuit board 210. In the process, the flexible component 230 is connected to an actuator/sensor device 240 using at least two conductor tracks 214 of the printed circuit board 210 for example (see FIG. 6). In the process, the position of the flexible component 230 in the flexible region 211 of the printed circuit board 210 is chosen taking into account a predetermined, maximally allowable disturbance of the actuator/sensor device 240 by the flexible component 230 for example, in such a way that a length of an electrical connection between the flexible component 230 and the actuator/sensor device 240 is minimal. When determining the predetermined maximally allowable disturbance of the actuator/sensor device 240 by the flexible component 230 to be assembled, the possible heat input in the actuator/sensor device 240 from the flexible component 230 and potential electromagnetic interference in the actuator/sensor device 240. caused by the flexible component 230, can be taken into account.

Although the present disclosure has been described with reference to exemplary embodiments, it is modifiable in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
200 Arrangement
210 Printed circuit board
211 Flexible region of the printed circuit board
212 Rigid region of the printed circuit board
213 Rigid region of the printed circuit board
214 Conductor track
220 Integrated circuit
230 Component
231 Substrate
240 Actuator/sensor device
300 Optical element
M1 Mirror
M2 Mirror
M3 Mirror
M4 Mirror
M5 Mirror
M6 Mirror
SW Threshold value
Z Assignment

What is claimed is:

1. An optical system, comprising:
an arrangement comprising a printed circuit board,
wherein the printed circuit board comprises:
a flexible region; and
a flexible component comprising an integrated circuit arranged in the flexible region, and
wherein the optical system is a lithography optical system.

2. The optical system of claim 1, wherein the integrated circuit comprises at least one member selected from the group consisting of a logic module, a processor, an analogue-digital converter, and a digital-analogue converter.

3. The optical system of claim 1, wherein the flexible component comprises a flexible substrate supporting the integrated circuit.

4. The optical system of claim 1, wherein the flexible region of the printed circuit board and the flexible component are bent state.

5. The optical system of claim 1, wherein the printed circuit board integrates the flexible region and the flexible component.

6. The optical system of claim 1, wherein the printed circuit board further comprises a rigid region connected to the flexible region.

7. The optical system of claim 1, wherein the printed circuit board further comprises two rigid regions, and the flexible region is between the two rigid regions.

8. The optical system of claim 1, further comprising a plurality of actuator/sensor devices connected to the flexible component via a conductor track of the printed circuit board.

9. The optical system of claim 8, further comprising a plurality of displaceable optical elements configured to guide radiation in the optical system, wherein an actuator/sensor device is assigned to a respective optical element so that the actuator/sensor device is configured to: i) displace the respective optical element; and/or ii) detect a parameter of the respective optical element.

10. The optical system of claim 9, wherein the actuator/sensor device is configured to detect a parameter of the respective optical element, and the parameter comprises a position of the respective optical element or a temperature in a region of the respective optical element.

11. The optical system of claim 1, further comprising a vacuum housing, wherein the arrangement is in the vacuum housing.

12. The optical system of claim 1, wherein the optical system comprises a member selected from the group consisting of a lithography illumination optical unit and a lithography projection optical unit.

13. The optical system of claim 12, wherein the integrated circuit comprises at least one member selected from the group consisting of a logic module, a processor, an analogue-digital converter, and a digital-analogue converter.

14. An apparatus, comprising:
an optical system according to claim 1,
wherein the apparatus is a lithography apparatus.

15. The apparatus of claim 14, further comprising:
an illumination optical unit; and
an projection optical unit,
wherein the optical system is in a member selected from the group consisting of the illumination optical unit and the projection optical unit.

16. The apparatus of claim 15, further comprising an EUV light source.

17. The apparatus of claim 16, wherein the optical system comprises a plurality of mirrors.

18. A method of making an optical system of a lithography apparatus, the method comprising:
disposing in the optical system a printed circuit board comprising a flexible region; and
disposing on the flexible region a flexible component comprising an integrated circuit.

19. The method of claim 18, further comprising connecting the flexible component to an actuator/sensor device via a conductor track of the printed circuit board.

20. The method of claim 19, choosing a position of the flexible component in the flexible region of the printed circuit board taking into account a predetermined, maximally allowable disturbance of the actuator/sensor device by the flexible component so that a length of an electrical connection between the flexible component and the actuator/sensor device is minimal.
